(19) United States
(12) Patent Application Publication
(10) Pub. No.: US 2016/0111626 A1
(43) Pub. Date: Apr. 21, 2016

(54) FLEXIBLE CONDUCTIVE MATERIAL AND TRANSDUCER

(71) Applicants: Sumitomo Riko Company Limited, Aichi-ken (JP); KYUSHU UNIVERSITY, NATIONAL UNIVERSITY CORPORATION, Fukuoka-ken (JP)

(72) Inventors: Yusaku TAKAGAKI, Aichi-ken (JP); Jun KOBAYASHI, Aichi-ken (JP); Yusuke YAMASHITA, Aichi-ken (JP); Hitoshi YOSHIKAWA, Aichi-ken (JP); Naotoshi NAKASHIMA, Fukuoka-ken (JP); Atsushi TAKAHARA, Fukuoka-ken (JP); Ryosuke MATSUNO, Fukuoka-ken (JP)

(73) Assignees: Sumitomo Riko Company Limited, Aichi-ken (JP); KYUSHU UNIVERSITY, NATIONAL UNIVERSITY CORPORATION, Fukuoka-ken (JP)

(21) Appl. No.: 14/983,749

(22) Filed: Dec. 30, 2015

Related U.S. Application Data
(63) Continuation of application No. PCT/JP2014/069559, filed on Jul. 24, 2014.

(30) Foreign Application Priority Data
Aug. 29, 2013 (JP) 2013-178110

(51) Int. Cl. H01L 41/047; H01B 1/24

(52) U.S. Cl. CPC H01L 41/0478; H01B 1/24

(57) ABSTRACT

A flexible conductive material of the present invention is formed by dispersing a conductive agent containing carbon nanotubes in a matrix that contains a polymer formed by amide bond formation or imide bond formation of a polycyclic aromatic component and an oligomer component and that has a glass transition point of 20° C. or less. The flexible conductive material of the present invention has good dispersibility of a conductive agent containing carbon nanotubes and has an excellent following performance to an expanding and shrinking substrate. A transducer of the present invention includes a dielectric layer made of a polymer, a plurality of electrodes with the dielectric layer interposed therebetween, and wirings connected to the respective electrodes, and at least either the electrodes or the wirings include the flexible conductive material of the present invention. The transducer of the present invention has a performance that is unlikely to deteriorate due to the electrodes or the wirings and has excellent durability.

### CLAIM FOR PRIORITY

This application is a Continuation of PCT/JP2014/069559 filed Jul. 24, 2014, and claims the priority benefit of Japanese application 2013-178110 filed Aug. 29, 2013, the contents of which is expressly incorporated by reference herein in its entirety.

### BACKGROUND OF THE INVENTION

1. Field of the Invention

The present invention relates to a flexible conductive material preferably used for electrodes, wirings, and other members of flexible transducers using polymer materials.

2. Description of Related Art

Highly flexible, compact and lightweight transducers have been developed by using polymer materials such as elastomers. Such a transducer includes a dielectric layer made of an elastomer between electrodes, for example. By changing the voltage applied across the electrodes, the dielectric layer is extended or shrunk. On this account, in a flexible transducer, electrodes and wirings are also required to have sufficient elasticity so as to follow deformation of the dielectric layer. A known material for such elastic electrodes and wirings is, for example, a conductive material produced by mixing an elastomer with a conductive agent such as carbon nanotubes, as described in the following Patent Document 1.

### RELATED ART DOCUMENTS

### Patent Documents

Patent Document 1: Japanese Patent Application Publication No. 2009-227985 (JP 2009-227985 A)
Patent Document 2: International Publication No. 2007/052739 (WO 2007/052739)
Patent Document 3: Japanese Patent Application Publication No. 2010-192296 (JP 2010-192296 A)
Patent Document 4: Japanese Patent Application Publication No. 2013-36021 (JP 2013-36021 A)
Patent Document 5: Japanese Patent Application Publication No. 2004-331777 (JP 2004-331777 A)
Patent Document 6: Japanese Patent Application Publication No. 2008-156560 (JP 2008-156560 A)

Carbon nanotubes have large aspect ratios (length/diameter). Thus, using carbon nanotubes as the conductive agent enables the formation of dense conductive pathways in a matrix and enables the achievement of high electric conductivity in comparison with using carbon black, for example. However, the carbon nanotubes, which have large aspect ratios, tend to aggregate. On this account, it is difficult to uniformly disperse carbon nanotubes in a matrix, and an intended electric conductivity is not obtained unfortunately.

As described in Patent Documents 2 to 6, it has been tried to improve the dispersibility of carbon nanotubes in solvents and matrices. For example, Patent Document 2 discloses a solubilizing agent using an aromatic polyimide, for carbon nanotubes. However, the aromatic polyimide has a rigid structure and thus has poor flexibility. On this account, the aromatic polyimide cannot be used singly as the matrix for flexible conductive materials. In addition, the aromatic polyimide has poor compatibility with an elastomer, and thus it is difficult to use the aromatic polyimide as a mixture with an elastomer.

Patent Document 6 discloses an imide-modified elastomer containing carbon nanotubes. However, the imide-modified elastomer described in Patent Document 6 is a material used for a transfer belt in image forming apparatuses, for example. A material that can bend is sufficient for the belts, and an elastic material causes problems for the purpose conversely. For instance, the elastomer component is exemplified by polyurethane having high crystallizability, and the imide-modified elastomer described in Patent Document 6 has poor flexibility. In addition, it is sufficient that a material for the belts should have electric conductivity to prevent electrification. On this account, the imide-modified elastomer described in Patent Document 6 requires no electric conductivity that is required for the materials of electrodes and wirings.

### SUMMARY OF THE INVENTION

In view of the above circumstances, the present invention has an object to provide a flexible conductive material that has good dispersibility of a conductive agent containing carbon nanotubes and has an excellent following performance to an expanding and shrinking substrate. Another object is to provide a transducer having a performance that is unlikely to deteriorate due to electrodes or wirings and having excellent durability.

(1) In order to solve the problems, a flexible conductive material of the present invention includes a conductive agent containing carbon nanotubes and dispersed in a matrix that contains a polymer formed by amide bond formation or imide bond formation of a polycyclic aromatic component and an oligomer component and that has a glass transition point of 20° C. or less.

The matrix of the flexible conductive material of the present invention contains a polymer (hereinafter appropriately called “polymer”) that is formed by amide bond formation or imide bond formation of a polycyclic aromatic component and an oligomer component. The polycyclic aromatic component in the polymer has excellent compatibility with the carbon nanotubes. This prevents the carbon nanotubes from aggregating and improves the dispersibility. Accordingly, even when containing the conductive agent in a comparatively small amount, the flexible conductive material of the present invention can achieve high electric conductivity because the carbon nanotubes having a large aspect ratio are highly dispersed.

The polymer contains an oligomer component, and the matrix has a glass transition point of 20° C. or less. Accordingly, the matrix is flexible. By selecting an elastomer compatible with the oligomer component, the polymer can be mixed with such an elastomer to constitute a matrix. In this case, the matrix obtains higher flexibility. As described above, the flexible conductive material of the present invention has high electric conductivity and has an excellent following performance to an expanding and shrinking substrate. In addition, the carbon nanotubes having a large aspect ratio are highly dispersed, and thus conductive pathways are unlikely to be broken and the electric resistance is unlikely to be increased even when the flexible conductive material is extended.

(2) A transducer of the present invention includes a dielectric layer made of a polymer, a plurality of electrodes with the dielectric layer interposed therebetween, and wirings connected to the respective electrodes. In the transducer, at least either the electrodes or the wirings include the flexible conductive material as described in the above aspect (1).

A transducer is an apparatus that converts a type of energy to another type of energy. The transducer is exemplified by transducers that perform the conversion between mechanical energy and electric energy, such as actuators, sensors, and power generation devices, and transducers that perform the conversion between acoustic energy and electric energy, such as speakers and microphones.

The electrodes and the wirings formed from the flexible conductive material of the present invention have flexibility and high electric conductivity and thus have an electric resistance that is unlikely to increase even when the electrodes and the wirings are extended. Thus, in the transducer of the present invention, the movement of the dielectric layer is unlikely to be restricted by the electrodes or wirings. In addition, the electrical resistance of the electrodes and the wirings is unlikely to increase even when extension and shrinkage are repeated. On this account, the transducer of the present invention has a performance that is unlikely to deteriorate due to the electrodes or the wirings. The transducer of the present invention therefore has excellent durability.

### BRIEF DESCRIPTION OF THE DRAWINGS

FIGS. 1A and 1B are schematic sectional views of an actuator as a first embodiment of a transducer of the present invention, in which FIG. 1A shows the actuator in the voltage off-state, and FIG. 1B shows the actuator in the voltage on-state;

FIG. 2 is a microscopic image of a conductive material of Example 2 (magnification: 100 times);

FIG. 3 is a microscopic image of a conductive material of Comparative Example 1 (magnification: 100 times);

FIG. 4 is a photograph of conductive paints of Example 2 and Comparative Example 1 (the left shows the conductive paint of Comparative Example 1, and the right shows the conductive paint of Example 2);

FIG. 5 is a microscopic image of a polymer film of Example 2 (magnification: 1,000 times);

FIG. 6 is a microscopic image of a polymer film of Comparative Example 2 (magnification: 1,000 times); and

FIG. 7 is a graph showing changes in volume resistivity relative to elongation ratio of conductive materials of Examples 1, 6, 10, 14, 18, and 19 and Comparative Examples 3 to 6.

### DESCRIPTION OF THE REFERENCE NUMERALS

1: Actuator (Transducer), 2: Dielectric Layer, 11a, 11b: Electrodes, 12a, 12b: Wirings, 13: Power Source

### DETAILED DESCRIPTION OF THE EMBODIMENTS

<Flexible Conductive Material>

A flexible conductive material of the present invention is prepared by dispersing a conductive agent containing carbon nanotubes in a matrix. The matrix contains a polymer formed by amide bond formation or imide bond formation of a polycyclic aromatic component and an oligomer component and has a glass transition point of 20° C. or less.

The polycyclic aromatic component in the polymer has a plurality of ring structures including aromatic rings. The number of the rings and arrangement of the rings are not particularly limited. The polycyclic aromatic component preferably has any of, for example, a benzene ring, a naphthalene ring, an anthracene ring, a phenanthrene ring, a pyrene ring, a perylene ring, and a naphthacene ring. In consideration of the flexibility of the polymer, a structure having a biphenyl structure or a naphthalene ring, in which benzene rings link, is preferred.

The oligomer component that forms an amide bond or an imide bond with the polycyclic aromatic component preferably has a weight average molecular weight of 100 or more and 100,000 or less in order to impart flexibility to the polymer. The weight average molecular weight is more preferably 10,000 or more. For example, the oligomer component is preferably a component that is compatible with any of a nitrile rubber, a chloroprene rubber, a chlorosulfonated polyethylene rubber, a urethane rubber, an acrylic rubber, an epichlorohydrin rubber, a fluororubber, a styrene-butadiene rubber, an isoprene rubber, a butadiene rubber, a butyl rubber, a silicone rubber, an ethylene-propylene copolymer, an ethylene-propylene-diene terpolymer, a polyether, and a natural rubber, which are added as necessary in order to impart flexibility to the matrix.

A polymer having a lower glass transition point (Tg) has higher flexibility. On this account, as the polymer has a lower Tg, the matrix becomes more flexible. The polymer desirably has a Tg of 20° C. or less, preferably 10° C. or less, and more preferably 0° C. or less.

The matrix can be composed of only the polymer or can be composed of the polymer and an additional elastomer. In the latter case, the elastomer can be selected from crosslinked rubbers or thermoplastic elastomers that have good compatibility with the polymer, specifically with the oligomer component contained in the polymer. The elastomer can be one or more elastomers selected from nitrile rubbers, chloroprene rubbers, chlorosulfonated polyethylene rubbers, urethane rubbers, acrylic rubbers, epichlorohydrin rubbers, fluororubbers, styrene-butadiene rubbers, isoprene rubbers, butadiene rubbers, butyl rubbers, silicone rubbers, ethylene-propylene copolymers, ethylene-propylene-diene terpolymers, and natural rubbers. The polymer and the elastomer can be simply mixed. When the polymer has a functional group such as a hydroxy group, the polymer can be crosslinked with the elastomer.

In the present specification, the compatibility between the polymer and the elastomer is determined as follows: First, a solvent in which the elastomer polymer can be dissolved is selected, and the polymer and the elastomer polymer are dissolved in the solvent to prepare a polymer solution. Next, the prepared polymer solution is applied onto a surface of a substrate, and the coating is dried by heating, for example. The obtained polymer film is then observed under a microscope, and the presence or absence of an area (separated area) where the polymer is separated is observed. Here, if a separated area having a maximum length of 1 μm or more is observed, the compatibility is determined to be poor, whereas if no separated area having a maximum length of 1 μm or more is observed, the compatibility is determined to be good, or the polymer is determined to be compatible with the elastomer.

The conductive agent contains carbon nanotubes. The carbon nanotubes may have a single layer structure or a multilayer structure. Specifically, single-walled carbon nanotubes (SGCNTs) produced by super growth method have a length of about hundreds of micrometers to several millimeters and have a larger aspect ratio. Thus, by using the SGCNTs even in a small amount, a high electric conductivity can be obtained. The conductive agent may contain an electrically conductive carbon powder such as carbon black and graphite or a powder of metal such as silver, gold, copper, nickel, rhodium, palladium, chromium, titanium, platinum, iron, and alloys thereof, for example, in addition to the carbon nanotube. These conductive powders may be used singly or as a mixture of two or more of them.

The amount of the conductive agent can be appropriately set in consideration of flexibility and electric conductivity of the flexible conductive material. For example, the amount of the conductive agent can be 30 parts by mass or less relative to 100 parts by mass of the matrix from the viewpoint of flexibility. The amount is more preferably 20 parts by mass or less. The flexible conductive material of the present invention in a natural state preferably has a volume resistivity of 1.00 Ω·cm or less. The flexible conductive material of the present invention satisfying both the flexibility and the electric conductivity is suitable as electrodes and wirings for transducers, flexible wiring boards, and other devices, as well as electromagnetic wave shields.

<Production Method of Flexible Conductive Material>

The flexible conductive material of the present invention can be produced as follows. First, a polymer is synthesized from the polycyclic aromatic compound and the oligomer. Next, the synthesized polymer and an elastomer polymer that is added as necessary are dissolved in an organic solvent to prepare a polymer solution. To the polymer solution, the conductive agent is added and dispersed with a bead mill or a similar apparatus to prepare a conductive paint. The conductive paint is then applied to a substrate and is dried, giving a thin film-like flexible conductive material. Alternatively, the flexible conductive material of the present invention can be produced by kneading raw materials with rolls or a kneader without using any solvent and then subjecting the kneaded materials to pressing, calendering, extruding, or other processing. The conductive paint may contain additives such as crosslinking agents, crosslinking promoters, crosslinking aids, plasticizers, process aids, age inhibitors, softeners, and coloring agents, as necessary.

The polycyclic aromatic compound used for synthesis of the polymer can be exemplified by naphthalene-1,4,5,8-tetracarboxylic dianhydride, 3,3′,4,4′-biphenyltetracarboxylic dianhydride, 3,4,9,10-perylenetetracarboxylic dianhydride, 4,4′-oxydiphthalic anhydride, perylo[1,12-bcd]thiophene-3,4,9,10-tetracarboxylic anhydride, 3,3′,4,4′-p-terphenyltetracarboxylic dianhydride, 3,3′,4,4′-benzophenonetetracarboxylic dianhydride, 3,3′,4,4′-diphenylsulfonetetracarboxylic dianhydride, 9H-xanthene-2,3,6,7-tetracarboxylic 2,3:6,7-dianhydride, and 4,4′-[m-sulfonylbis (phenylenesulfanyl)]diphthalic anhydride. The oligomer can be an oligomer having a terminal modified with an amino group. The case in which a polymer is synthesized by amide bond formation of the polycyclic aromatic component and the oligomer component has such an advantage that the case eliminates a heating step that is required for the synthesis of the polymer formed by imide bond formation of both the components and that is for converting the amide bond into an imide bond. In addition, the case has such an advantage that the carboxy group formed from the amide bond can be used to perform a crosslinking reaction or a modification reaction.

The method of applying the conductive paint may be various known methods. Examples of the method include printing methods such as inkjet printing, flexo printing, gravure printing, screen printing, pad printing, and lithography; dipping; spraying, and bar coating.

Examples of the substrate include elastic elastomer sheet and bendable resin sheets made from polyimide, polyethylene, polyethylene terephthalate (PET), polyethylene naphthalate (PEN), and similar resins. When formed on a surface of an elastic substrate, the flexible conductive material of the present invention can more reliably achieve such advantageous effects that the flexibility is high and the electrical resistance is unlikely to increase even when the material is extended. When the matrix is composed of only the polymer, a cover layer may be stacked so as to cover a surface of a conductive layer composed of the flexible conductive material of the present invention in order to improve the following performance and adhesiveness to a substrate. Adhesion layers, other conductive layers, or other layers can be stacked so as to interpose a conductive layer composed of the flexible conductive material of the present invention.

<Transducer>

A transducer of the present invention includes a dielectric layer made of a polymer, a plurality of electrodes with the dielectric layer interposed therebetween, and wirings connected to the respective electrodes. The transducer of the present invention may have a multilayer structure in which dielectric layers and electrodes are alternately stacked.

The dielectric layer is made of a polymer, that is, a resin or an elastomer. The elastomer has excellent elasticity and thus is preferred. In order to increase the displacement and the generative force, specifically, an elastomer having a high relative dielectric constant is preferably used. The elastomer specifically, preferably has a relative dielectric constant (at a frequency of 100 Hz) at normal temperature of 2 or more and more preferably 5 or more. For example, the elastomer preferably has a polar functional group such as an ester group, a carboxy group, a hydroxy group, a halogen group, an amido group, a sulfone group, a urethane group, and nitrile group. Alternatively, the elastomer preferably contains a low molecular weight polar compound having such a polar functional group. Preferred examples of the elastomer include silicone rubber, nitrile rubber, hydrogenated nitrile rubber, EPDM, acrylic rubber, urethane rubber, epichlorohydrin rubber, chlorosulfonated polyethylene, and chlorinated polyethylene. Here, the term “made of a polymer” means that the base material of the dielectric layer is a resin or an elastomer. Thus, the dielectric layer may contain other components such as additives in addition to the elastomer or resin component.

The thickness of the dielectric layer can be appropriately determined depending on an intended application of the transducer. For example, for an actuator, the dielectric layer preferably has a small thickness in view of downsizing, low-potential driving, and a larger displacement. In this case, the dielectric layer preferably has a thickness of 1 μm or more and 1,000 μm (1 mm) or less in consideration of dielectric breakdown. The thickness is more preferably 5 μm or more and 200 μm or less.

At least either the electrodes or the wirings include the flexible conductive material of the present invention. The structure and the production method of the flexible conductive material of the present invention are as described above, and thus are not described here. In the electrodes and the wirings of the transducer of the present invention, the preferred embodiment of the flexible conductive material of the present invention is preferably employed. An embodiment of an actuator will next be described as an embodiment of the transducer of the present invention.

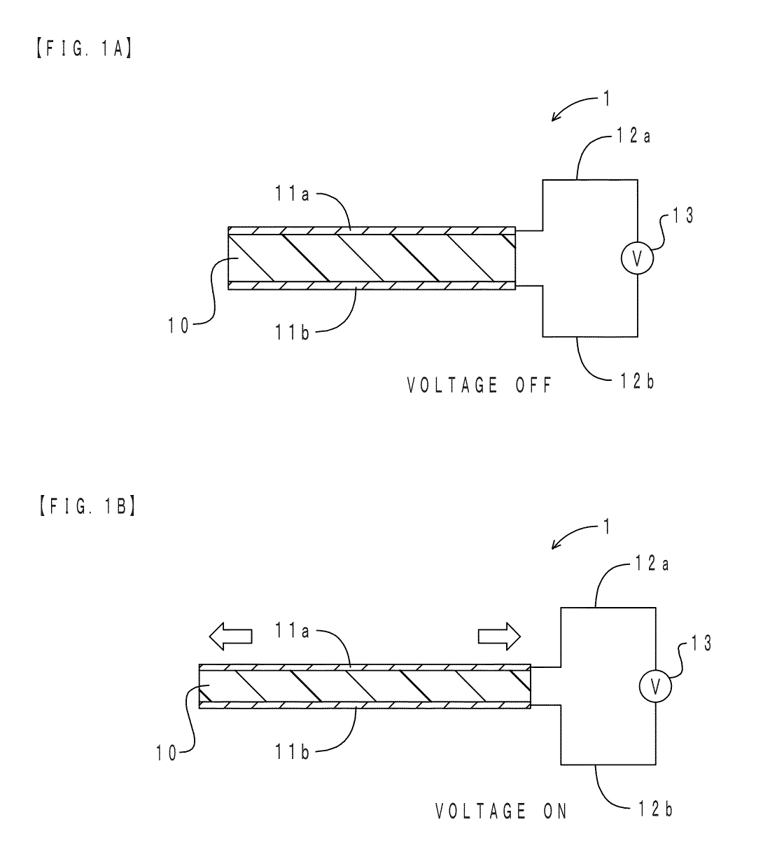

FIGS. 1A and 1B are schematic sectional views of an actuator of the present embodiment. FIG. 1A shows the actuator in the voltage-off state, and FIG. 1B shows the actuator in the voltage-on state.

As shown in FIGS. 1A and 1B, an actuator 1 includes a dielectric layer 10, electrodes 11a, 11b, and wirings 12a, 12b. The dielectric layer 10 is made of a silicone rubber. The electrode 111a is disposed so as to cover substantially the whole top face of the dielectric layer 10. Similarly, the electrode 1b is disposed so as to cover substantially the whole bottom face of the dielectric layer 10. The electrodes 11a, 11b are connected to a power source 13 through the wirings 12a, 12b, respectively. The electrodes 11a, 11b are made of the flexible conductive material of the present invention, and the flexible conductive material is prepared by dispersing single-walled carbon nanotubes in a matrix containing a polymer and a silicone rubber. The polymer is NTCDA-polysiloxaneimide (polymer (A-2) in Examples described later) synthesized from naphthalene-1,4,5,8-tetracarboxylic dianhydride (NTCDA) and a both-end-amino-modified silicone. The matrix has a glass transition point of −46° C.

To switch the actuator from the off state to the on state, a voltage is applied between the pair of electrodes 11a, 11b. By the application of the voltage, the dielectric layer 10 has such a smaller thickness as to extend in the parallel direction with the faces of the electrodes 11a, 11b as shown by the hollow arrows in FIG. 1B. Accordingly, the actuator 1 outputs a drive force in the vertical direction and the lateral direction in the drawings.

According to the present embodiment, the electrodes 11a, 11b have excellent flexibility and elasticity. On this account, the movement of the dielectric layer 10 is unlikely to be restricted by the electrodes 11a, 11b. Thus, the actuator 1 can obtain a large force and displacement. In addition, the electrodes 11a, 11b have high electric conductivity. The electrodes 11a, 11b have an electrical resistance that is unlikely to increase even when extension and shrinkage are repeated. On this account, the actuator 1 has a performance that is unlikely to deteriorate due to the electrodes 11a, 11b. The actuator 1 therefore has excellent durability.

### EXAMPLES

The present invention will next be described in further detail with reference to Examples.

<Production of Polymer>

[Polymers (A-1), (A-2)]

As the polymers, naphthalene-1,4,5,8-tetracarboxylic dianhydride (NTCDA)-polysiloxanamide and NTCDA-polysiloxaneimide were produced. The reaction process is shown in Formula (A).

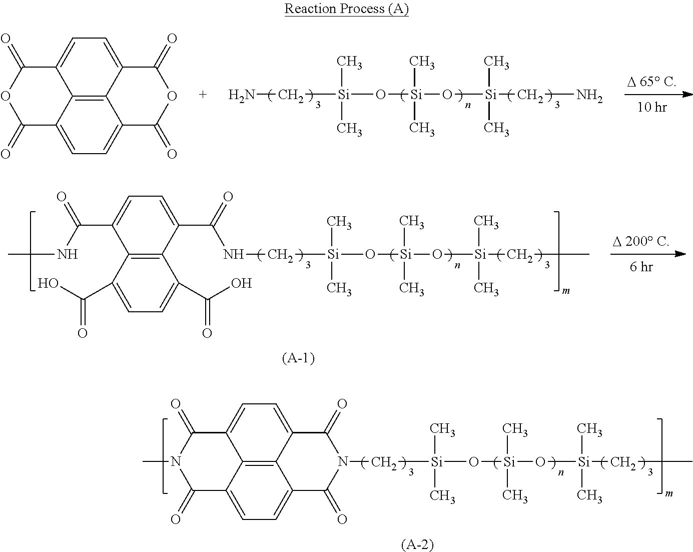

First, 5.03 g (18.76 mmol) of NTCDA (a molecular weight of 268.18) was weighed and placed in a three-necked flask together with 200 ml of tetrahydrofuran (THF) as the solvent, and nitrogen bubbling was performed for 30 minutes. Next, 30.00 g (18.76 mmol) of both-end-amino-modified silicone (“X22-161A” manufactured by Shin-Etsu Chemical Co., Ltd., a molecular weight of 1,600) was weighed and added to the three-necked flask with stirring, and the mixture was heated and refluxed under a nitrogen atmosphere at 65° C. for 10 hours to perform polymerization reaction. After the completion of the reaction, THF was removed by vacuum drying, giving NTCDA-polysiloxanamide having the structure of Formula (A-1). Subsequently, the obtained NTCDA-polysiloxanamide was placed in a recovery flask, then was heated and refluxed at 200° C. for 6 hours, and was dried under reduced pressure, giving NTCDA-polysiloxaneimide having the structure of Formula (A-2).

The obtained NTCDA-polysiloxaneimide was subjected to infrared spectroscopic (IR) measurement, and peaks derived from imide were observed at 1,780 cm⁻¹, 1,720 cm⁻¹, and 1,380 cm⁻¹ in the infrared absorption spectrum. The molecular weight was determined by gel permeation chromatography (GPC), and the weight average molecular weight was 26,800. The glass transition point was determined with a differential scanning calorimeter (DSC, “DSC6220” manufactured by Hitachi High-Tech Science Corporation) to be −45° C.

[Polymers (B-1), (B-2)]

As the polymers, NTCDA-polyetheramide and NTCDA-polyetherimide were produced. The reaction process is shown in Formula (B).

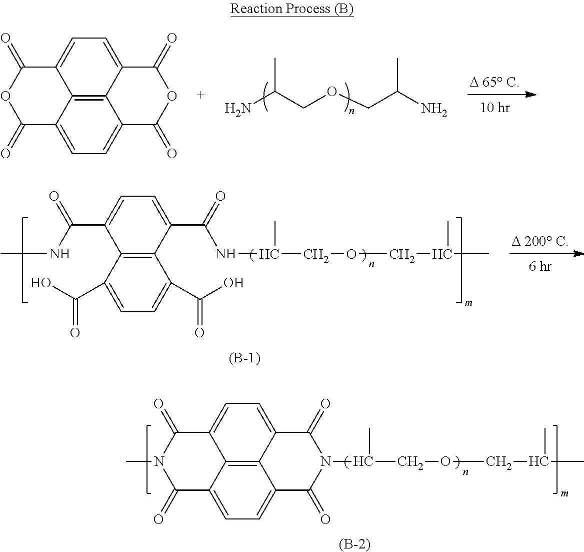

First, 4.02 g (15.00 mmol) of NTCDA (a molecular weight of 268.18) was weighed and placed in a three-necked flask together with 200 ml of THF, and nitrogen bubbling was performed for 30 minutes. Next, 30.00 g (15.00 mmol) of poly(propylene glycol) bis(2-aminopropyl ether) (manufactured by Aldrich, a molecular weight of 2,000) was weighed and added to the three-necked flask with stirring, and the mixture was heated and refluxed under a nitrogen atmosphere at 65° C. for 10 hours to perform polymerization reaction. After the completion of the reaction, THF was removed by vacuum drying, giving NTCDA-polyetheramide having the structure of Formula (B-1).

The obtained NTCDA-polyetheramide was subjected to IR measurement, and peaks derived from amide were observed at 1,670 cm⁻¹ and 1,550 cm⁻¹ in the infrared absorption spectrum. The molecular weight was determined by GPC, and the weight average molecular weight was 52,300. The glass transition point was determined with the DSC to be −55° C.

Subsequently, the NTCDA-polyetheramide was placed in a recovery flask, then was heated and refluxed at 200° C. for 6 hours, and was dried under reduced pressure, giving NTCDA-polyetherimide having the structure of Formula (B-2). The obtained NTCDA-polyetherimide was subjected to IR measurement, and peaks derived from imide were observed at 1,780 cm⁻¹, 1,720 cm⁻¹, and 1,380 cm⁻¹ in the infrared absorption spectrum. The molecular weight was determined by GPC, and the weight average molecular weight was 55,900. The glass transition point was determined with the DSC to be −53° C.

[Polymers (C-1), (C-2)]

As the polymers, 3,3′,4,4′-biphenyltetracarboxylic dianhydride (BPDA)-polyetheramide and BPDA-polyetherimide were produced. The reaction process is shown in Formula (C).

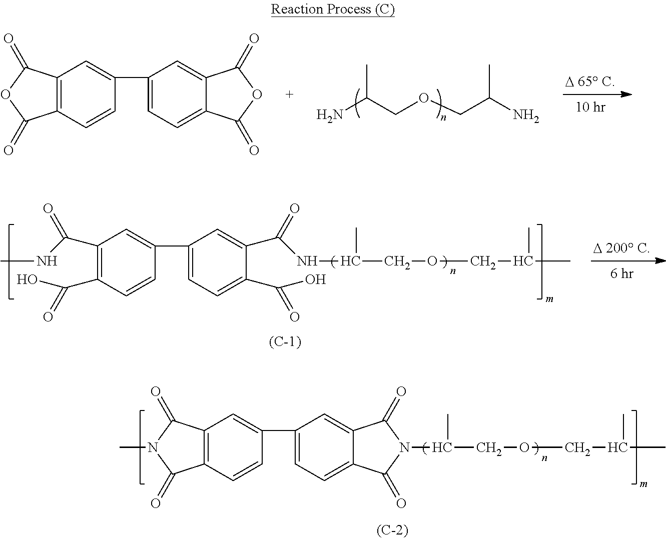

First, 4.41 g (15.00 mmol) of BPDA (a molecular weight of 294.22) was weighed and placed in a three-necked flask together with 200 ml of THF, and nitrogen bubbling was performed for 30 minutes. Next, 30.00 g (15.00 mmol) of poly(propylene glycol) bis(2-aminopropyl ether) (the same as the above) was weighed and added to the three-necked flask with stirring, and the mixture was heated and refluxed under a nitrogen atmosphere at 65° C. for 10 hours to perform polymerization reaction. After the completion of the reaction, THF was removed by vacuum drying, giving BPDA-polyetheramide having the structure of Formula (C-1).

The obtained BPDA-polyetheramide was subjected to IR measurement, and peaks derived from amide were observed at 1,670 cm⁻¹ and 1,550 cm⁻¹ in the infrared absorption spectrum. The molecular weight was determined by GPC, and the weight average molecular weight was 42,500. The glass transition point was determined with the DSC to be −47° C.

Subsequently, the BPDA-polyetheramide was placed in a recovery flask, then was heated and refluxed at 200° C. for 6 hours, and was dried under reduced pressure, giving BPDA-polyetherimide having the structure of Formula (C-2). The obtained BPDA-polyetherimide was subjected to IR measurement, and peaks derived from imide were observed at 1,780 cm⁻¹, 1,720 cm⁻¹, and 1,380 cm⁻¹ in the infrared absorption spectrum. The molecular weight was determined by GPC, and the weight average molecular weight was 54,160. The glass transition point was determined with the DSC to be −45° C.

[Polymers (D-1), (D-2)]

As the polymers, 3,4,9,10-perylenetetracarboxylic dianhydride (PTCDA)-polyetheramide and PTCDA-polyetherimide were produced. The reaction process is shown in Formula (D).

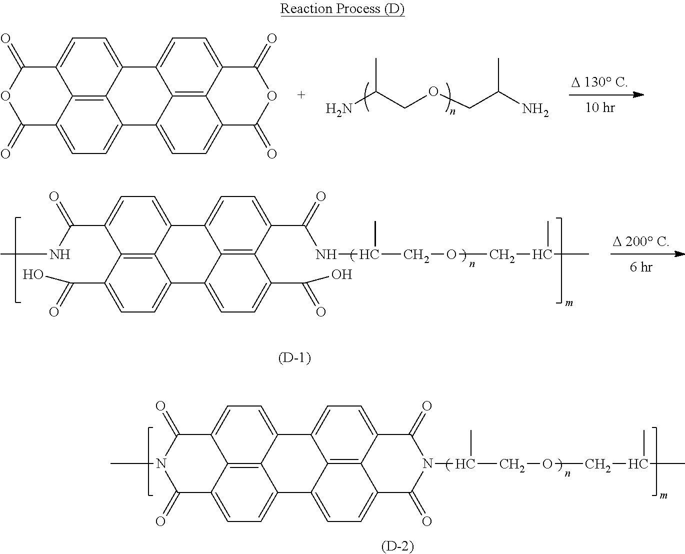

First 5.88 g (15.00 mmol) of PTCDA (a molecular weight of 392.32) was weighed and placed in a three-necked flask together with 200 ml of N,N-dimethylformamide (DMF) as the solvent, and nitrogen bubbling was performed for 30 minutes. Next, 30.00 g (15.00 mmol) of poly(propylene glycol) bis(2-aminopropyl ether) (the same as the above) was weighed and added to the three-necked flask with stirring, and the mixture was heated and refluxed under a nitrogen atmosphere at 130° C. for 10 hours to perform polymerization reaction. After the completion of the reaction, DMF was removed by vacuum drying, giving PTCDA-polyetheramide having the structure of Formula (D-1).

The obtained PTCDA-polyetheramide was subjected to IR measurement, and peaks derived from amide were observed at 1,670 cm⁻¹ and 1,550 cm⁻¹ in the infrared absorption spectrum. The molecular weight was determined by GPC, and the weight average molecular weight was 13,200. The glass transition point was determined with the DSC to be −2.5° C.

Subsequently, the PTCDA-polyetheramide was placed in a recovery flask, then was heated and refluxed at 200° C. for 6 hours, and was dried under reduced pressure, giving PTCDA-polyetherimide having the structure of Formula (D-2). The obtained PTCDA-polyetherimide was subjected to IR measurement, and peaks derived from imide were observed at 1,780 cm⁻¹, 1,720 cm⁻¹, and 1,380 cm⁻¹ in the infrared absorption spectrum. The molecular weight was determined by GPC, and the weight average molecular weight was 13,750. The glass transition point was determined with the DSC to be −2.7° C.

[Polymers (E-1), (E-2)]

As the polymers, 4,4′-oxydiphthalic anhydride (OPDA)-polyetheramide and OPDA-polyetherimide were produced. The reaction process is shown in Formula (E).

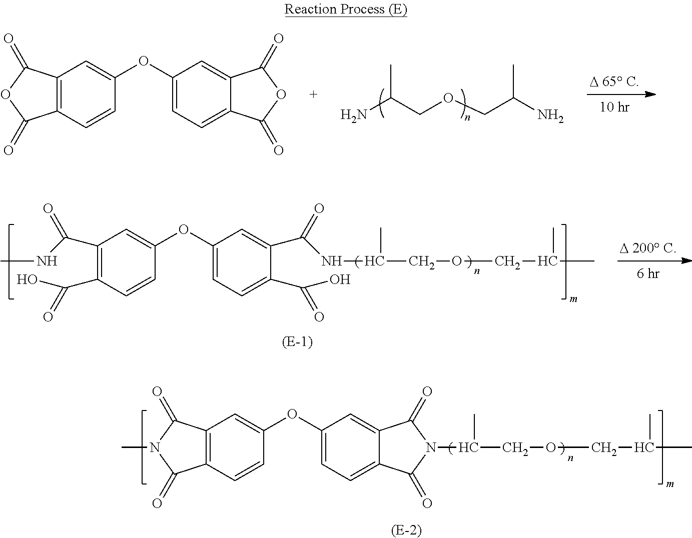

First, 4.65 g (15.00 mmol) of OPDA (a molecular weight of 310.21) was weighed and placed in a three-necked flask together with 200 ml of THF, and nitrogen bubbling was performed for 30 minutes. Next, 30.00 g (15.00 mmol) of poly(propylene glycol) bis(2-aminopropyl ether) (the same as the above) was weighed and added to the three-necked flask with stirring, and the mixture was heated and refluxed under a nitrogen atmosphere at 65° C. for 10 hours to perform polymerization reaction. After the completion of the reaction, THF was removed by vacuum drying, giving OPDA-polyetheramide having the structure of Formula (E-1).

The obtained OPDA-polyetheramide was subjected to IR measurement, and peaks derived from amide were observed at 1,670 cm⁻¹ and 1,550 cm⁻¹ in the infrared absorption spectrum. The molecular weight was determined by GPC, and the weight average molecular weight was 32,500. The glass transition point was determined with the DSC to be −45° C.

Subsequently, the OPDA-polyetheramide was placed in a recovery flask, then was heated and refluxed at 200° C. for 6 hours, and was dried under reduced pressure, giving OPDA-polyetherimide having the structure of Formula (E-2). The obtained OPDA-polyetherimide was subjected to IR measurement, and peaks derived from imide were observed at 1,780 cm⁻¹, 1,720 cm⁻¹, and 1,380 cm⁻¹ in the infrared absorption spectrum. The molecular weight was determined by GPC, and the weight average molecular weight was 32,600. The glass transition point was determined with the DSC to be −46° C.

<Production of Conductive Material>

The polymers produced were used to produce conductive materials of Examples 1 to 21. The conductive materials of Examples 1 to 21 were included in the flexible conductive material of the present invention. For comparison, conductive materials of Comparative Examples 1 to 6 were produced without using the polymers produced.

### Example 1

In toluene as the solvent, 100 parts by mass of NTCDA-polysiloxaneimide as polymer (A-2) was dissolved to prepare a polymer solution. To the prepared polymer solution, 5 parts by mass of single-walled carbon nanotubes (“Super Growth CNT” manufactured by National Institute of Advanced Industrial Science and Technology) were added as the conductive agent, and the mixture was dispersed in a bead mill (“DYNO-MILL” manufactured by Shinmaru Enterprises) containing glass beads having a diameter of 0.5 mm, giving a conductive paint. The peripheral speed of the bead mill was 10 m/s. The conductive paint prepared was applied onto a surface of a PET substrate by bar coating, and the coating was heated at 150° C. for 1 hour to be dried. In this manner, a thin film-like conductive material having a thickness of 30 μm was produced.

### Example 2

In toluene, 50 parts by mass of silicone rubber polymer (“KE-1935” manufactured by Shin-Etsu Chemical Co., Ltd.) was dissolved to prepare a polymer solution. To the prepared polymer solution, 50 parts by mass of NTCDA-polysiloxaneimide as polymer (A-2) and 5 parts by mass of single-walled carbon nanotubes (the same as the above) were added, and the mixture was dispersed in a bead mill (the same as the above) containing glass beads having a diameter of 0.5 mm, giving a conductive paint. The peripheral speed of the bead mill was 10 m/s. In the same manner as in Example 1, the prepared conductive paint was applied onto a surface of a PET substrate and the coating was dried, giving a thin film-like conductive material having a thickness of 30 μm. The glass transition point of the matrix of the present conductive material produced from the silicone rubber polymer and polymer (A-2) was determined with the DSC to be −46° C.

### Example 3

In methyl ethyl ketone as the solvent, 82 parts by mass of acrylic rubber polymer (“Nipol (registered trademark) AR53L” manufactured by Zeon Corporation) was dissolved to prepare a polymer solution. To the prepared polymer solution, 18 parts by mass of NTCDA-polyetheramide as polymer (R-1) and 15 parts by mass of multiwalled carbon nanotubes (“NC7000” manufactured by Nanocyl) as the conductive agent were added, and the mixture was dispersed in a bead mill (the same as the above) containing glass beads having a diameter of 0.5 mm, giving a conductive paint. The peripheral speed of the bead mill was 10 m/s. In the same manner as in Example 1, the prepared conductive paint was applied onto a surface of a PET substrate and the coating was dried, giving a thin film-like conductive material having a thickness of 30 μm. The glass transition point of the matrix of the present conductive material produced from the acrylic rubber polymer and polymer (B-1) was determined with the DSC to be −53° C.

### Example 4

A conductive paint was prepared and a conductive material was produced in the same manner as in Example 3 except that polymer (B-1) was changed to NTCDA-polyetherimide as polymer (B-2). The glass transition point of the matrix of the present conductive material produced from the acrylic rubber polymer and polymer (B-2) was determined with the DSC to be −50° C.

### Example 5

A conductive paint was prepared and a conductive material was produced in the same manner as in Example 3 except that polymer (B-1) was changed to BPDA-polyetheramide as polymer (C-1). The glass transition point of the matrix of the present conductive material produced from the acrylic rubber polymer and polymer (C-1) was determined with the DSC to be −46° C.

### Example 6

A conductive paint was prepared and a conductive material was produced in the same manner as in Example 3 except that polymer (B-1) was changed to BPDA-polyetherimide as polymer (C-2). The glass transition point of the matrix of the present conductive material produced from the acrylic rubber polymer and polymer (C-2) was determined with the DSC to be −45° C.

### Example 7

A conductive paint was prepared and a conductive material was produced in the same manner as in Example 3 except that polymer (B-1) was changed to PTCDA-polyetheramide as polymer (D-1). The glass transition point of the matrix of the present conductive material produced from the acrylic rubber polymer and polymer (D-1) was determined with the DSC to be −41° C.

### Example 8

A conductive paint was prepared and a conductive material was produced in the same manner as in Example 3 except that polymer (B-1) was changed to PTCDA-polyetherimide as polymer (D-2). The glass transition point of the matrix of the present conductive material produced from the acrylic rubber polymer and polymer (D-2) was determined with the DSC to be −42° C.

### Example 9

A conductive paint was prepared and a conductive material was produced in the same manner as in Example 3 except that polymer (B-1) was changed to OPDA-polyetheramide as polymer (E-1). The glass transition point of the matrix of the present conductive material produced from the acrylic rubber polymer and polymer (E-1) was determined with the DSC to be −46° C.

### Example 10

A conductive paint was prepared and a conductive material was produced in the same manner as in Example 3 except that polymer (B-1) was changed to OPDA-polyetherimide as polymer (E-2). The glass transition point of the matrix of the present conductive material produced from the acrylic rubber polymer and polymer (E-2) was determined with the DSC to be −47° C.

### Example 11

A conductive paint was prepared and a conductive material was produced in the same manner as in Example 3 except that the conductive agent was changed to 13 parts by mass of multiwalled carbon nanotubes (the same as the above) and 2 parts by mass of single-walled carbon nanotubes (the same as the above).

### Example 12

A conductive paint was prepared and a conductive material was produced in the same manner as in Example 4 except that the conductive agent was changed to 13 parts by mass of multiwalled carbon nanotubes (the same as the above) and 2 parts by mass of single-walled carbon nanotubes (the same as the above).

### Example 13

A conductive paint was prepared and a conductive material was produced in the same manner as in Example 5 except that the conductive agent was changed to 13 parts by mass of multiwalled carbon nanotubes (the same as the above) and 2 parts by mass of single-walled carbon nanotubes (the same as the above).

### Example 14

A conductive paint was prepared and a conductive material was produced in the same manner as in Example 6 except that the conductive agent was changed to 13 parts by mass of multiwalled carbon nanotubes (the same as the above) and 2 parts by mass of single-walled carbon nanotubes (the same as the above).

### Example 15

A conductive paint was prepared and a conductive material was produced in the same manner as in Example 7 except that the conductive agent was changed to 13 parts by mass of multiwalled carbon nanotubes (the same as the above) and 2 parts by mass of single-walled carbon nanotubes (the same as the above).

### Example 16

A conductive paint was prepared and a conductive material was produced in the same manner as in Example 8 except that the conductive agent was changed to 13 parts by mass of multiwalled carbon nanotubes (the same as the above) and 2 parts by mass of single-walled carbon nanotubes (the same as the above).

### Example 17

A conductive paint was prepared and a conductive material was produced in the same manner as in Example 9 except that the conductive agent was changed to 13 parts by mass of multiwalled carbon nanotubes (the same as the above) and 2 parts by mass of single-walled carbon nanotubes (the same as the above).

### Example 18

A conductive paint was prepared and a conductive material was produced in the same manner as in Example 10 except that the conductive agent was changed to 13 parts by mass of multiwalled carbon nanotubes (the same as the above) and 2 parts by mass of single-walled carbon nanotubes (the same as the above).

### Example 19

A conductive paint was prepared and a conductive material was produced in the same manner as in Example 6 except that the conductive agent was changed to 10 parts by mass of single-walled carbon nanotubes (the same as the above).

### Example 20

A conductive paint was prepared and a conductive material was produced in the same manner as in Example 19 except that the amount of the acrylic rubber polymer was changed to 91 parts by mass and the amount of the BPDA-polyetherimide as polymer (C-2) was changed to 9 parts by mass. The glass transition point of the matrix of the present conductive material produced from the acrylic rubber polymer and polymer (C-2) was determined with the DSC to be −43° C.

### Example 21

A conductive paint was prepared and a conductive material was produced in the same manner as in Example 19 except that the amount of the acrylic rubber polymer was changed to 64 parts by mass and the amount of the BPDA-polyetherimide as polymer (C-2) was changed to 36 parts by mass. The glass transition point of the matrix of the present conductive material produced from the acrylic rubber polymer and polymer (C-2) was determined with the DSC to be −47° C.

### Example 22

A conductive paint was prepared and a conductive material was produced in the same manner as in Example 19 except that the acrylic rubber polymer was changed to urethane rubber polymer 1 (“VYLON (registered trademark) GK570” manufactured by Toyobo Co., Ltd.). The glass transition point of the matrix of the present conductive material produced from urethane rubber polymer 1 and polymer (C-2) was determined with the DSC to be −3° C.

### Example 23

A conductive paint was prepared and a conductive material was produced in the same manner as in Example 19 except that the acrylic rubber polymer was changed to urethane rubber polymer 2 (“VYLON (registered trademark) GM400” manufactured by Toyobo Co., Ltd.). The glass transition point of the matrix of the present conductive material produced from urethane rubber polymer 2 and polymer (C-2) was determined with the DSC to be 16° C.

### Comparative Example 1

A conductive material was produced by using only a conventional rubber polymer without using the polymer. First, 100 parts by mass of silicone rubber polymer (the same as the above) used in Example 2 was dissolved in toluene to prepare a polymer solution. To the prepared polymer solution, 5 parts by mass of single-walled carbon nanotubes (the same as the above) were added as the conductive agent, and the mixture was dispersed in a bead mill (the same as the above) containing glass beads having a diameter of 0.5 mm, giving a conductive paint. The peripheral speed of the bead mill was 10 m/s. In the same manner as in Example 1, the prepared conductive paint was applied onto a surface of a PET substrate and the coating was dried, giving a thin film-like conductive material having a thickness of 30 μm. The glass transition point of the silicone rubber as the matrix of the present conductive material was determined with the DSC to be −45° C.

### Comparative Example 2

A conductive paint was prepared and a conductive material was produced in the same manner as in Example 2 except that in place of polymer (A-2), 50 parts by mass of NTCDA as the polycyclic aromatic compound used for the production of the polymer was added. The glass transition point of the matrix of the present conductive material produced from the silicone rubber polymer and the NTCDA was determined with the DSC to be −45° C.

### Comparative Example 3

A conductive material was produced by using only a conventional rubber polymer without using the polymer. First, 100 parts by mass of acrylic rubber polymer (the same as the above) used in Example 3 was dissolved in methyl ethyl ketone to prepare a polymer solution. To the prepared polymer solution, 15 parts by mass of multiwalled carbon nanotubes (the same as the above) were added as the conductive agent, and the mixture was dispersed in a bead mill (the same as the above) containing glass beads having a diameter of 0.5 mm, giving a conductive paint. The peripheral speed of the bead mill was 10 m/s. In the same manner as in Example 1, the prepared conductive paint was applied onto a surface of a PET substrate and the coating was dried, giving a thin film-like conductive material having a thickness of 30 μm. The glass transition point of the acrylic rubber as the matrix of the present conductive material was determined with the DSC to be −42° C.

### Comparative Example 4

A conductive paint was prepared and a conductive material was produced in the same manner as in Comparative Example 3 except that the conductive agent was changed to 13 parts by mass of multiwalled carbon nanotubes (the same as the above) and 2 parts by mass of single-walled carbon nanotubes (the same as the above).

### Comparative Example 5

A conductive paint was prepared and a conductive material was produced in the same manner as in Example 11 except that in place of polymer (B-1), 18 parts by mass of NTCDA as the polycyclic aromatic compound used for the production of the polymer was added. The glass transition point of the matrix of the present conductive material produced from the acrylic rubber polymer and the NTCDA was determined with the DSC to be −42° C.

### Comparative Example 6

A conductive paint was prepared and a conductive material was produced in the same manner as in Comparative Example 3 except that the conductive agent was changed to 10 parts by mass of single-walled carbon nanotubes (the same as the above).

### Comparative Example 7

A conductive paint was prepared and a conductive material was produced in the same manner as in Comparative Example 6 except that the acrylic rubber polymer was changed to urethane rubber polymer 1 (the same as the above). The glass transition point of urethane rubber polymer 1 as the matrix of the present conductive material was determined with the DSC to be 0° C.

### Comparative Example 8

A conductive paint was prepared and a conductive material was produced in the same manner as in Comparative Example 6 except that the acrylic rubber polymer was changed to urethane rubber polymer 2 (the same as the above). The glass transition point of urethane rubber polymer 2 as the matrix of the present conductive material was determined with the DSC to be 21° C.

<Evaluation of Conductive Material>

[Evaluation Method]

(1) Electric Conductivity

First, the volume resistivity of a conductive material in a natural state (initial state) before extension was determined. The volume resistivity was measured in accordance with the parallel terminal electrode method in JIS K6271 (2008). The insulating resin holder for holding a conductive material (test piece) used in the measurement of the volume resistivity was a commercially available rubber sheet (“VHB (registered trademark) 4910” manufactured by Sumitomo 3M). Next, a conductive material was extended with the holder at an elongation ratio of 30% in a uniaxial direction, and the volume resistivity was measured. The elongation ratio is a value calculated in accordance with Equation (i).

Elongation ratio (%)=(ΔL₀/L₀)×100 (i)

[L₀: a gauge length of a test piece; and ΔL₀: an increase in the gauge length of the test piece by elongation]

(2) Flexibility

Tensile test was carried out in accordance with JIS K6254: 2010, and the static shear modulus at 25% strain was measured. For the measurement, a strip-like No. 1 test piece was used and the tensile speed was 100 mm/min.

(3) Dispersibility of Carbon Nanotubes

A laser particle size analyzer (“Microtrac MT3300EII” manufactured by Nikkiso Co., Ltd.) was used to determine the particle size distribution of carbon nanotubes contained in a conductive paint. From the obtained particle size distribution, a median diameter (d50) was calculated. It is supposed that fewer aggregates of carbon nanotubes lead to a smaller value of d50. Thus, the d50 value can be used as an index for evaluating the dispersibility of carbon nanotubes.

(4) Compatibility Between Polymer and Elastomer

In Examples 2 to 23, which contains the silicone rubber, the acrylic rubber, or the urethane rubber polymer 1 or 2 as the matrix, the compatibility between the polymer and the rubber polymer was evaluated. First, the polymer and the rubber polymer were dissolved in a solvent to prepare a polymer solution, and then the solution was applied onto a surface of a PET substrate and the coating was heated at 150° C. for 1 hour to be dried. As the solvent, toluene was used for the silicone rubber, and methyl ethyl ketone was used for the acrylic rubber and the urethane rubber polymers 1 and 2. The obtained polymer film was observed under a microscope. If a separated area having a maximum length of 1 μm or more was observed, the compatibility was evaluated as poor (indicated by x in Table 1 and Table 2), whereas if the separated area was not observed, the compatibility was evaluated as good (indicated by O in Table 1 to Table 3).

For the comparison, as for Comparative Examples 2 and 5, the polycyclic aromatic compound and the rubber polymer were dissolved in a solvent to prepare a polymer solution, and then a polymer film was formed from the polymer solution and the compatibility between the polycyclic aromatic compound and the rubber polymer was evaluated.

Evaluation Result

The formulation of raw materials in each conductive material and the evaluation results of Examples and Comparative Examples are shown in Table 1 to Table 3.

TABLE 1

| | | | Example 1 | Example 2 | Example 3 | Example 4 | Example 5 | Example 6 | Example 7 |
|---|---|---|---|---|---|---|---|---|---|
| Raw | Elastomer | Silicone rubber | — | 50 | — | — | — | — | — |
| material | | Acrylic rubber | — | — | 82 | 82 | 82 | 82 | 82 |
| [parts by | | Urethane rubber 1 | — | — | — | — | — | — | — |
| mass] | | Urethane rubber 2 | — | — | — | — | — | — | — |
| | Polymer | NTCDA-polysiloxaneimide (A-2) | 100 | 50 | — | — | — | — | — |
| | | NTCDA-polyetheramide (B-1) | — | — | 18 | — | — | — | — |
| | | NTCDA-polyetherimide (B-2) | — | — | — | 18 | — | — | — |
| | | BPDA-polyetheramide (C-1) | — | — | — | — | 18 | — | — |
| | | BPDA-polyetherimide (C-2) | — | — | — | — | — | 18 | — |
| | | PTCDA-polyetheramide (D-1) | — | — | — | — | — | — | 18 |
| | | PTCDA-polyetherimide (D-2) | — | — | — | — | — | — | — |
| | | ODPA-polyetheramide (E-1) | — | — | — | — | — | — | — |
| | | ODPA-polyetherimide (E-2) | — | — | — | — | — | — | — |
| | Polycyclic aromatic compound (NTCDA) | | — | — | — | — | — | — | — |
| | Conductive | Multiwalled carbon nanotubcs | — | — | 15 | 15 | 15 | 15 | 15 |
| | agent | Single-walled carbon nanotubes | 5 | 5 | — | — | — | — | — |
| | Solvent | Methyl ethyl ketone | — | — | 2185 | 2185 | 2185 | 2185 | 2185 |
| | | Toluene | 2185 | 2185 | — | — | — | — | — |

| | | | | | | | | |
|---|---|---|---|---|---|---|---|---|
| Evaluation | Initial volume resistivity [Ω · cm] | 0.41 | 0.46 | 0.33 | 0.24 | 0.22 | 0.13 | 0.36 |
| | Volume resistivity at 30% elongation [Ω · cm] | 2.50 | 0.98 | 0.92 | 0.62 | 0.57 | 0.57 | 1.67 |
| | Elastic modulus [MPa] | 80.0 | 62.0 | 5.7 | 1.8 | 5.9 | 3.4 | 16.0 |
| | Particle size distribution (d50) [μm] | 27.8 | 28.3 | 13.7 | 13.7 | 22.3 | 13.3 | 17.6 |
| | Compatibility between polymer and elastomer | — | ∘ | ∘ | ∘ | ∘ | ∘ | ∘ |
| | Glass transition point of matrix [° C.] | −45 | −46 | −53 | −50 | −46 | −45 | −41 |

| | | | | | | Comparative | Comparative | Comparative |
|---|---|---|---|---|---|---|---|---|
| | | | Example 8 | Example 9 | Example 10 | Example 1 | Example 2 | Example 3 |
| Raw | Elastomer | Silicone rubber | — | — | — | 100 | 50 | — |
| material | | Acrylic rubber | 82 | 82 | 82 | — | — | 100 |
| [parts by | | Urethane rubber 1 | — | — | — | — | — | — |
| mass] | | Urethane rubber 2 | — | — | — | — | — | — |
| | Polymer | NTCDA-polysiloxaneimide (A-2) | — | — | — | — | — | — |
| | | NTCDA-polyetherimade (B-1) | — | — | — | — | — | — |
| | | NTCDA-polyetherimide (B-2) | — | — | — | — | — | — |
| | | BPDA-polyetheramade (C-1) | — | — | — | — | — | — |
| | | BPDA-polyetherimide (C-2) | — | — | — | — | — | — |
| | | PTCDA-polyetheramide (D-1) | — | — | — | — | — | — |
| | | PTCDA-polyetherimide (D-2) | 18 | — | — | — | — | — |
| | | ODPA-polyetheramide (E-1) | — | 18 | — | — | — | — |
| | | ODPA-polyetherimide (E-2) | — | — | 18 | — | — | — |

| Polycyclic aromatic compound (NTCDA) | | — | — | — | — | 50 | — |
|---|---|---|---|---|---|---|---|
| Conductive | Multiwalled carbon nanotubcs | 15 | 15 | 15 | — | — | 15 |
| agent | Single-walled carbon nanotubes | — | — | — | 5 | 5 | — |
| Solvent | Methyl ethyl ketone | 2185 | 2185 | 2185 | — | — | 2185 |
| | Toluene | — | — | — | 2185 | 2185 | — |

| | | | | | | | |
|---|---|---|---|---|---|---|---|
| Evaluation | Initial volume resistivity [Ω · cm] | 0.38 | 0.15 | 0.12 | 1.05 | 4.45 | 1.45 |
| | Volume resistivity at 30% elongation [Ω · cm] | 1.59 | 0.56 | 0.34 | 2.56 | 6.08 | 2.23 |
| | Elastic modulus [MPa] | 14.7 | 6.8 | 7.9 | 58.0 | 134.0 | 9.0 |
| | Particle size distribution (d50) [μm] | 12.6 | 22.6 | 18.9 | 62.4 | 89.3 | 38.3 |
| | Compatibility between polymer and elastomer | ∘ | ∘ | ∘ | — | x | — |
| | Glass transition point of matrix [° C.] | −42 | −46 | −47 | −45 | −45 | −42 |

TABLE 2

| | | | Example 11 | Example 12 | Example 13 | Example 14 | Example 15 | Example 16 |
|---|---|---|---|---|---|---|---|---|
| Raw | Elastomer | Silicone rubber | — | — | — | — | — | — |
| material | | Acrylic rubber | 82 | 82 | 82 | 82 | 82 | 82 |
| [parts by | | Urethane rubber 1 | — | — | — | — | — | — |
| mass] | | Urethane rubber 2 | — | — | — | — | — | — |
| | Polymer | NTCDA-polysiloxancimide (A-2) | — | — | — | — | — | — |
| | | NTCDA-polyetheramide (B-1) | 18 | — | — | — | — | — |
| | | NTCDA-polyetherimide (B-2) | — | 18 | — | — | — | — |
| | | BPDA-polyetheramide (C-1) | — | — | 18 | — | — | — |
| | | BPDA-polyetherimide (C-2) | — | — | — | 18 | — | — |
| | | PTCDA-polyetheramide (D-1) | — | — | — | — | 18 | — |
| | | PTCDA-polyetherimide (D-2) | — | — | — | — | — | 18 |
| | | ODPA-polyetheramide (E-1) | — | — | — | — | — | — |
| | | ODPA-polyetherimide (E-2) | — | — | — | — | — | — |
| | Polycyclic aromatic compound (NTCDA) | | — | — | — | — | — | — |
| | Conductive | Multiwalled carbon nanotubes | 13 | 13 | 13 | 13 | 13 | 13 |
| | agent | Single-walled carbon nanotubes | 2 | 2 | 2 | 2 | 2 | 2 |
| | Solvent | Methyl ethyl ketone | 2185 | 2185 | 2185 | 2185 | 2185 | 2185 |
| | | Toluene | — | — | — | — | — | — |

| | | | | | | | |
|---|---|---|---|---|---|---|---|
| Evaluation | Initial volume resistivity [Ω · cm] | 0.13 | 0.23 | 0.09 | 0.07 | 0.33 | 0.19 |
| | Volume resistivity at 30% elongation [Ω · cm] | 0.54 | 0.56 | 0.26 | 0.23 | 1.03 | 1.56 |
| | Elastic modulus [MPa] | 8.7 | 7.5 | 10.0 | 7.2 | 17.5 | 22.3 |
| | Particle size distribution (d50) [μm] | 30.3 | 29.5 | 21.8 | 19.8 | 38.9 | 35.3 |
| | Compatibility between polymer and elastomer | ∘ | ∘ | ∘ | ∘ | ∘ | ∘ |
| | Glass transition point of matrix [° C.] | −53 | −50 | −46 | −45 | −41 | −42 |

| | | | | | Comparative | Comparative |
|---|---|---|---|---|---|---|
| | | | Example 17 | Example 18 | Example 4 | Example 5 |
| Raw | Elastomer | Silicone rubber | — | — | — | — |
| material | | Acrylic rubber | 82 | 82 | 100 | 82 |
| [parts by | | Urethane rubber 1 | — | — | — | — |
| mass] | | Urethane rubber 2 | — | — | — | — |
| | Polymer | NTCDA-polysiloxancimide (A-2) | — | — | — | — |
| | | NTCDA-polyetheramide (B-1) | — | — | — | — |
| | | NTCDA-polyetherimide (B-2) | — | — | — | — |
| | | BPDA-polyetheramide (C-1) | — | — | — | — |
| | | BPDA-polyetherimide (C-2) | — | — | — | — |
| | | PTCDA-polyetheramide (D-1) | — | — | — | — |
| | | PTCDA-polyetherimide (D-2) | — | — | — | — |
| | | ODPA-polyetheramide (E-1) | 18 | — | — | — |
| | | ODPA-polyetherimide (E-2) | — | 18 | — | — |

| Polycyclic aromatic compound (NTCDA) | | — | — | — | 18 |
|---|---|---|---|---|---|
| Conductive | Multiwalled carbon nanotubes | 13 | 13 | 13 | 13 |
| agent | Single-walled carbon nanotubes | 2 | 2 | 2 | 2 |
| Solvent | Methyl ethyl ketone | 2185 | 2185 | 2185 | 2185 |
| | Toluene | — | — | — | — |

| | | | | | |
|---|---|---|---|---|---|
| Evaluation | Initial volume resistivity [Ω · cm] | 0.08 | 0.09 | 1.02 | 3.03 |
| | Volume resistivity at 30% elongation [Ω · cm] | 0.32 | 0.16 | 1.56 | 4.03 |
| | Elastic modulus [MPa] | 11.3 | 12.2 | 14.3 | 35.3 |
| | Particle size distribution (d50) [μm] | 25.3 | 26.8 | 55.3 | 65.4 |
| | Compatibility between polymer and elastomer | ∘ | ∘ | — | x |
| | Glass transition point of matrix [° C.] | −46 | −47 | −42 | −42 |

TABLE 3

| | | | | | | | | Compar- | Compar- | Compar- |
|---|---|---|---|---|---|---|---|---|---|---|
| | | | | | | | | ative | ative | ative |
| | | | Exam- | Exam- | Exam- | Exam- | Exam- | Exam- | Exam- | Exam- |
| | | | ple 19 | ple 20 | ple 21 | ple 22 | ple 23 | ple 6 | ple 7 | ple 8 |
| Raw | Elastomer | Silicone rubber | — | — | — | — | — | — | — | — |
| material | | Acrylic rubber | 82 | 91 | 64 | — | — | 100 | — | — |
| [parts by | | Urethane rubber 1 | — | — | — | 82 | — | — | 100 | — |
| mass] | | Urethane rubber 2 | — | — | — | — | 82 | — | — | 100 |
| | Polymer | NTCDA-polysiloxaneimide (A-2) | — | — | — | — | — | — | — | — |
| | | NTCDA-polyetheramide (B-1) | — | — | — | — | — | — | — | — |
| | | NTCDA-polyetherimide (B-2) | — | — | — | — | — | — | — | — |
| | | BPDA-polyetheramide (C-1) | — | — | — | — | — | — | — | — |
| | | BPDA-polyetherimide (C-2) | 18 | 9 | 36 | 18 | 18 | — | — | — |
| | | PTCDA-polyetheramide (D-1) | — | — | — | — | — | — | — | — |
| | | PTCDA-polyetherimide (D-2) | — | — | — | — | — | — | — | — |
| | | ODPA-polyetheramide (E-1) | — | — | — | — | — | — | — | — |
| | | ODPA-polyetherimide (E-2) | — | — | — | — | — | — | — | — |
| | Polycyclic aromatic compound (NTCDA) | | — | — | — | — | — | — | — | — |
| | Conductive | Multiwalled carbon nanotubes | — | — | — | — | — | — | — | — |
| | agent | Single-walled carbon nanotubes | 10 | 10 | 10 | 10 | 10 | 10 | 10 | 10 |
| | Solvent | Methyl ethyl ketone | 2185 | 2185 | 2185 | 2185 | 2185 | 2185 | 2185 | 2185 |
| | | Toluene | — | — | — | — | — | — | — | — |

| | | | | | | | | | |
|---|---|---|---|---|---|---|---|---|---|
| Evaluation | Initial volume resistivity [Ω · cm] | 0.05 | 0.85 | 0.07 | 0.65 | 0.98 | 0.23 | 1.03 | 1.34 |
| | Volume resistivity at 30% elongation [Ω · cm] | 0.07 | 0.20 | 0.09 | 1.02 | 5.45 | 2.14 | 10.23 | 12.23 |
| | Elastic modulus [MPa] | 40.0 | 48.0 | 35.0 | 280.0 | 420.0 | 54.0 | 320.0 | 450.0 |
| | Particle size distribution (d50) [μm] | 10.0 | 25.0 | 15.0 | 38.4 | 39.5 | 35.0 | 56.4 | 60.4 |
| | Compatibility between polymer and elastomer | ∘ | ∘ | ∘ | ∘ | ∘ | — | — | — |
| | Glass transition point of matrix [° C.] | −45 | −43 | −47 | −3 | 16 | −42 | 0 | 21 |

As shown in Table 1, the conductive material of Example 1 in which the matrix contained only the polymer had a small initial volume resistivity of 1.00 Ω·cm or less. The particle size distribution, d50, was also small as compared with the conductive materials of Comparative Examples. From the results, the carbon nanotubes were determined to have good dispersibility. The elastic modulus and the volume resistivity at an elongation of 30% of the conductive material of Example 1 were slightly larger than those of the conductive materials of the other Examples in which the matrix contained an elastomer.

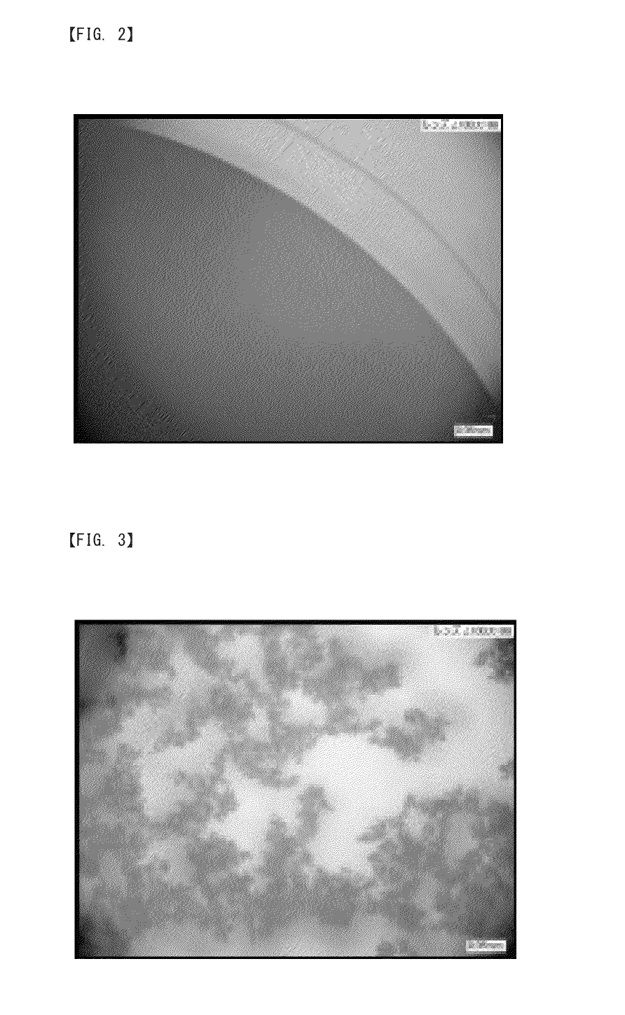

Comparison of Example 2 with Comparative Examples 1 and 2, in which the matrix contained a silicone rubber, reveals that the conductive material of Example 2 containing the polymer had a smaller initial volume resistivity and also had a smaller increase in volume resistivity at elongation. The conductive material of Example 2 had a small particle size distribution, d50, which also indicates an improvement of dispersibility of carbon nanotubes. FIG. 2 shows a microscopic image of the conductive material of Example 2 (magnification: 100 times). FIG. 3 shows a microscopic image of the conductive material of Comparative Example 1 (magnification: 100 times). As shown in FIG. 2 and FIG. 3, it was ascertained that the carbon nanotubes were unevenly distributed in the conductive material of Comparative Example 1, whereas the carbon nanotubes were dispersed to form a uniform film in the conductive material of Example 2.

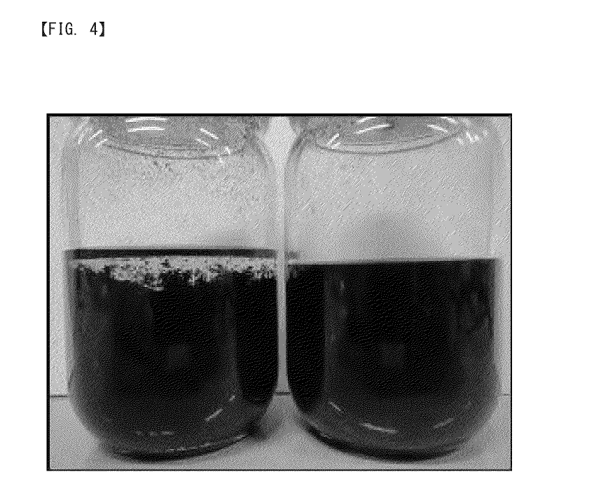

FIG. 4 shows a photograph of the conductive paints of Example 2 and Comparative Example 1. The left in FIG. 4 is a photograph of the conductive paint of Comparative Example 1, and the right is a photograph of the conductive paint of Example 2. As shown in FIG. 4, it was ascertained that the carbon nanotubes aggregated in the conductive paint of Comparative Example 1, whereas the carbon nanotubes were uniformly dispersed in the conductive paint of Example 2.

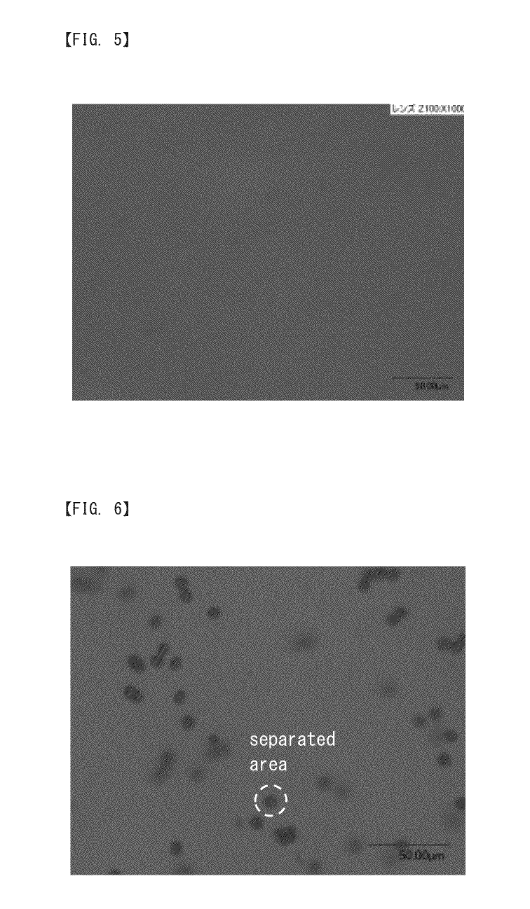

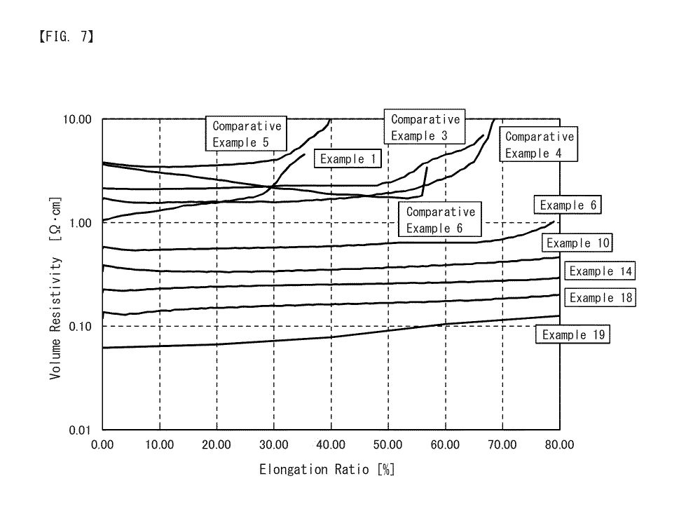

As for the compatibility between the polymer and the elastomer, FIG. 5 shows a microscopic image of the polymer film of Example 2 (magnification: 1,000 times). FIG. 6 shows a microscopic image of the polymer film of Comparative Example 2 (magnification: 1,000 times). As shown in FIG. 5 and FIG. 6, separated areas having a maximum length of 1 μm or more were dotted in the polymer film of Comparative Example 2, whereas no separated area having a maximum length of 1 μm or more was observed in the polymer film of Example 2. As described above, it was ascertained that the compatibility between polymer (A-2) and the silicone rubber polymer used in Example 2 was good.

When Examples 3 to 10 are compared with Comparative Example 3, in which the matrix contained an acrylic rubber and multiwalled carbon nanotubes were added as the conductive agent, it was ascertained that the conductive materials of Examples 3 to 10 containing the polymers had a smaller initial volume resistivity and also had a smaller increase in volume resistivity at elongation. The conductive materials of Examples 3 to 10 had a small particle size distribution, d50, which also indicates an improvement of dispersibility of carbon nanotubes. The compatibility between the polymers and the acrylic rubber polymer used in Examples 3 to 10 was good.

As shown in Table 2, comparison of Examples 11 to 18 with Comparative Examples 4 and 5, in which the matrix contained an acrylic rubber and both single-walled carbon nanotubes and multiwalled carbon nanotubes were added as the conductive agent, reveals that the conductive materials of Examples 11 to 18 containing the polymers had a smaller initial volume resistivity. The volume resistivities at elongation of the conductive materials of Examples 11 to 18 were equal to or smaller than those of the conductive materials of Comparative Examples 4 and 5. The conductive materials of Examples 11 to 18 had a small particle size distribution, d50, which also indicates an improvement of dispersibility of carbon nanotubes. As with Examples 3 to 10, the compatibility between the polymers and the acrylic rubber polymer used in Examples 11 to 18 was good. The compatibility between the polycyclic aromatic compound and the acrylic rubber polymer used in Comparative Example 5 was poor.

As shown in Table 3, comparison of Examples 19 to 21 with Comparative Example 6, in which the matrix contained an acrylic rubber and single-walled carbon nanotubes were added as the conductive agent, reveals that the conductive materials of Examples 19 to 21 containing the polymer had a smaller initial volume resistivity and had a smaller increase in volume resistivity at elongation. In particular, the conductive material of Example 19, in which the amount of BPDA-polyetherimide as polymer (C-2) was 18 parts by mass, and the conductive material of Example 21, in which the amount was 36 parts by mass, had volume resistivities that remained almost unchanged even in an elongation condition. The conductive materials of Examples 19 to 21 had a small particle size distribution, d50, which also indicates an improvement of dispersibility of carbon nanotubes. The conductive materials of Examples 19 to 21 containing the polymer had a smaller elastic modulus than that of the conductive material of Comparative Example 6. This result reveals that addition of the BPDA-polyetherimide having a flexible polyether skeleton improves the flexibility. The polymer used in Examples 19 to 21 is the same as the polymer used in Examples 6 and 14. Thus, the compatibility between the polymer and the acrylic rubber polymer was good.

Comparison of Examples 22 and 23 with Comparative Examples 7 and 8 in turn, in which the matrix contained a urethane rubber and single-walled carbon nanotubes were added as the conductive agent, reveals that the conductive materials of Examples 22 and 23 containing the polymer had a smaller initial volume resistivity and had a smaller increase in volume resistivity at elongation. The conductive materials of Examples 22 and 23 had a small particle size distribution, d50, which also indicates an improvement of dispersibility of carbon nanotubes. The conductive material of Example 22 containing the polymer had a smaller elastic modulus than that of the conductive material of Comparative Example 7. Similarly, the conductive material of Example 23 containing the polymer had a smaller elastic modulus than that of the conductive material of Comparative Example 8. This result reveals that addition of the BPDA-polyetherimide having a flexible polyether skeleton improves the flexibility. The compatibility between the polymer and the urethane rubber polymers used in Examples 22 and 23 was good.

FIG. 7 shows changes in volume resistivity relative to elongation ratio of the conductive materials of Examples 1, 6, 10, 14, 18, and 19 and Comparative Examples 3 to 6. The volume resistivity was determined by the method described in [Evaluation Method], (1) Electric conductivity. As shown in FIG. 7, the conductive materials of Examples 6, 10, 14, 18, and 19, in which the matrix contained polymer (C-2) or polymer (E-2) and the acrylic rubber, had volume resistivities that remained almost unchanged even when the elongation ratio was increased to 80%.

The flexible conductive material of the present invention is preferably used as electrodes and wirings of flexible transducers, flexible wiring boards, and similar devices and as electromagnetic wave shields used for electronic devices, wearable devices, and similar devices. The flexible conductive material of the present invention can be used for electrodes, wirings, and electromagnetic wave shields, thereby improving the durability of electronic devices mounted in flexible members such as moving parts of robots, care equipment, and interior members of transportation equipment.

What is claimed is:

1. A flexible conductive material, comprising a conductive agent containing carbon nanotubes and dispersed in a matrix that contains a polymer formed by amide bond formation or imide bond formation of a polycyclic aromatic component and an oligomer component and an elastomer compatible with the oligomer component and that has a glass transition point of 20° C. or less, wherein
the flexible conductive material has a volume resistivity at an elongation of 30% of 2.50 Ω·cm or less.

2. The flexible conductive material according to claim 1, wherein
the polycyclic aromatic component has any of a benzene ring, a naphthalene ring, an anthracene ring, a phenanthrene ring, a pyrene ring, a perylene ring, and a naphthacene ring.

3. The flexible conductive material according to claim 1, wherein
the oligomer component is compatible with any of a nitrile rubber, a chloroprene rubber, a chlorosulfonated polyethylene rubber, a urethane rubber, an acrylic rubber, an epichlorohydrin rubber, a fluororubber, a styrene-butadiene rubber, an isoprene rubber, a butadiene rubber, a butyl rubber, a silicone rubber, an ethylene-propylene copolymer, an ethylene-propylene-diene terpolymer, a polyether, and a natural rubber.

4. The flexible conductive material according to claim 1, wherein
the conductive agent is contained in an amount of 30 parts by mass or less relative to 100 parts by mass of the matrix, and
the flexible conductive material in a natural state has a volume resistivity of 1.00 Ω·cm or less.

5. The flexible conductive material according to claim 1, wherein the flexible conductive material is used for at least one of an electrode, a wiring, or an electromagnetic wave shield.

6. A transducer comprising:
a dielectric layer made of a polymer;
a plurality of electrodes with the dielectric layer interposed therebetween; and
wirings connected to the respective electrodes, wherein
at least either the electrodes or the wirings include the flexible conductive material as claimed in claim 1.
